(19) United States
(12) Patent Application Publication
(10) Pub. No.: US 2025/0157907 A1
(43) Pub. Date: May 15, 2025

(54) SEMICONDUCTOR PACKAGE INCLUDING TRENCH STRUCTURE, MANUFACTURING METHOD THEREOF, AND STRIP SUBSTRATE

(71) Applicant: SK hynix Inc., Icheon-si Gyeonggi-do (KR)

(72) Inventors: In Young JANG, Icheon-si Gyeonggi-do (KR); Bok Gyu MIN, Icheon-si Gyeonggi-do (KR)

(73) Assignee: SK hynix Inc., Icheon-si Gyeonggi-do (KR)

(21) Appl. No.: 18/613,931

(22) Filed: Mar. 22, 2024

(30) Foreign Application Priority Data
Nov. 9, 2023 (KR) 10-2023-0154247

(51) Int. Cl. H01L 23/498; H01L 21/56; H01L 21/66; H01L 23/00; H01L 23/31; H01L 23/552

(52) U.S. Cl. CPC H01L 23/49838; H01L 21/561; H01L 22/12; H01L 23/3128; H01L 23/552; H01L 24/97; H01L 2224/97

(57) ABSTRACT

A semiconductor package includes a package substrate including a plurality of trenches that are disposed at a periphery of a bottom surface of the package substrate; a semiconductor chip disposed on a top surface of the package substrate; an encapsulation part disposed on the top surface of the package substrate that seals the semiconductor chip; and a shield layer disposed on a surface of the encapsulation part and a side surface of the package substrate. At least one of the plurality of trenches includes first and second regions that are continuously disposed in a direction that is perpendicular to a direction in which a portion of the shield layer that contacts the corresponding trench extends, and the first and second regions different widths.

### CROSS-REFERENCE TO RELATED APPLICATION

The present application claims priority under 35 U.S.C. § 119(a) to Korean Patent Application No. 10-2023-0154247 filed in the Korean Intellectual Property Office on Nov. 9, 2023, which is incorporated herein by reference in its entirety.

### BACKGROUND

### 1. Technical Field

The disclosed technology generally relates to a semiconductor technology, and more particularly, to a semiconductor package including a trench structure, a manufacturing method thereof, and a strip structure.

### 2. Related Art

A semiconductor chip cannot be electrically connected to and exchange signals with an external device by itself. In addition, the semiconductor chip includes fine circuits, and thus, may be easily damaged by an external shock. A semiconductor package electrically connects the semiconductor chip and seals and packages the semiconductor chip to withstand external shocks so that the semiconductor chip has a physical function and a shape. In general, the semiconductor package is manufactured at a strip level and is then separated into an individual semiconductor package through a sawing process.

### SUMMARY

In an embodiment, a semiconductor package may include: a package substrate including a plurality of trenches which are disposed at a periphery of a bottom surface; a semiconductor chip disposed on a top surface of the package substrate; an encapsulation part disposed on the top surface of the package substrate, and sealing the semiconductor chip; and a shield layer disposed on a surface of the encapsulation part and a side surface of the package substrate, wherein at least one of the plurality of trenches includes first and second regions which are continuously disposed in a direction that is perpendicular to a direction in which a portion of the shield layer that contacts the corresponding trench extends, and wherein the first and second regions have different widths.

In an embodiment, a method for manufacturing a semiconductor package may include: forming a strip substrate that has a package region and a package separation region surrounding the package region and that includes a plurality of trenches disposed at an edge of the package region of a bottom surface; mounting a semiconductor chip on the package region of a top surface of the strip substrate; sealing the semiconductor chip with an encapsulation part; forming an individualized semiconductor package by cutting the encapsulation part and the strip substrate along the package separation region through a sawing process; inspecting an appearance of trenches of the semiconductor package; evaluating a capability of the sawing process based on a result of the inspecting of the appearance of the trenches; and forming a shield layer on a side surface of a package substrate of the semiconductor package and a surface of the encapsulation part, wherein each of the plurality of trenches of the strip substrate includes first and second regions that are continuously disposed in a direction that is perpendicular to a direction in which a portion of the package separation region that contacts the corresponding trench extends, wherein the first and second regions different widths, and wherein the inspecting of the appearance of the trenches includes checking a presence of the first and second regions of the trenches of the semiconductor package.

In an embodiment, a strip substrate may include: a substrate body having a package region and a package separation region that surrounds the package region; and a plurality of trenches disposed along an edge of a bottom surface of the package region, wherein each of the plurality of trenches includes first and second regions that are continuously disposed in a direction that is perpendicular to a direction in which a portion of the package separation region that contacts the corresponding trench extends, and wherein the first and second regions have different widths.

### BRIEF DESCRIPTION OF THE DRAWINGS

FIG. 1 is a bottom view illustrating a semiconductor package based on an embodiment of the disclosed technology.

FIG. 2 is a cross-sectional view taken along the line I-I′ of FIG. 1.

FIG. 3 is a cross-sectional view taken along the line II-II′ of FIG. 1.

FIG. 4 is a cross-sectional view taken along the line III-III′ of FIG. 1.

FIG. 5 is a bottom view illustrating a semiconductor package based on an embodiment of the disclosed technology.

FIG. 6 is a cross-sectional view schematically illustrating a package substrate based on an embodiment of the disclosed technology.

FIG. 7 is a top view schematically illustrating a strip substrate based on an embodiment of the disclosed technology.

FIG. 8 is a cross-sectional view schematically illustrating a part of the strip substrate based on the embodiment of the disclosed technology.

FIGS. 9 and 10 are bottom views illustrating strip substrates based on embodiments of the disclosed technology.

FIGS. 11 to 14, FIG. 15A to FIG. 15C, FIGS. 16A, 16B, 17A, 17B, 18A, and 18B are views showing a method for manufacturing a semiconductor package based on an embodiment of the disclosed technology.

### DETAILED DESCRIPTION

Hereinafter, embodiments of the present disclosure will be described in detail with reference to the accompanying drawings. In the following description, the same elements will be designated by the same reference numerals although they are shown in different drawings. Further, in the following description of the present disclosure, a detailed description of known functions and configurations incorporated herein will be omitted when it may make the subject matter of the present disclosure rather unclear. It is to be noticed that the terms “comprising,” “having,” “including” and so on, used in the description and claims, should not be interpreted as being restricted to the means listed thereafter unless specifically stated otherwise. Where an indefinite or definite article is used when referring to a singular noun, e.g., “a,” “an” and “the,” this may include a plural of that noun unless specifically stated otherwise.

Also, in describing the components of the disclosure, there may be terms used like first, second, A, B, (a), and (b). These are solely for the purpose of differentiating one component from another component but do not limit the substances, order, sequence or number of the components.

In descriptions for the positional relationships of components, in the case in which it is described that at least two components are “connected,” “coupled” or “linked,” it is to be understood that the at least two components may be directly “connected,” “coupled” or “linked” but may be indirectly “connected,” “coupled” or “linked” with another component interposed between the two components. Here, another component may be included in at least one of the at least two components which are “connected,” “coupled” or “linked” with each other.

In descriptions for time flow relationships of components, an operating method or a fabricating method, in the case in which pre and post relationships in terms of time or pre and post relationships in terms of flow are described, for example, by “after,” “following,” “next” or “before,” non-continuous cases may be included unless “immediately” or “directly” is used.

In the case in which a numerical value for a component or its corresponding information (e.g., level, etc.) is mentioned, even though there is no separate explicit description, the numerical value or its corresponding information can be interpreted as including an error range that may be caused by various factors (for example, a process variable, an internal or external shock, noise, etc.).

Hereinafter, various embodiments of the disclosed technology will be described in detail with reference to the accompanying drawings.

Embodiments of the disclosed technology are directed to a semiconductor package including a trench structure, a manufacturing method thereof, and a strip substrate.

According to the embodiments of the disclosed technology, it is possible to provide a semiconductor package including a trench structure, a manufacturing method thereof, and a strip substrate.

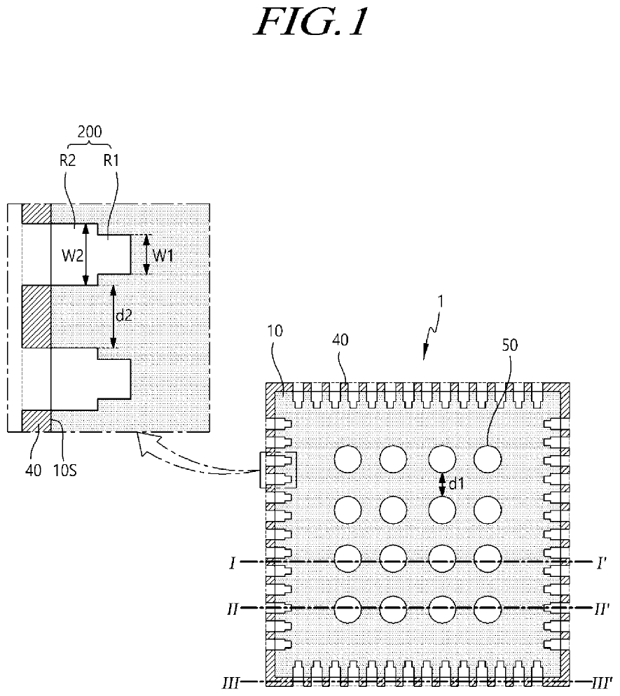

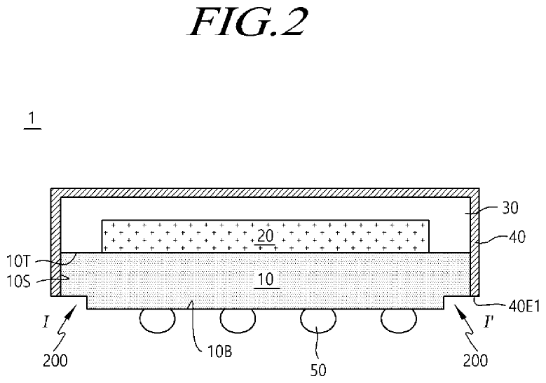

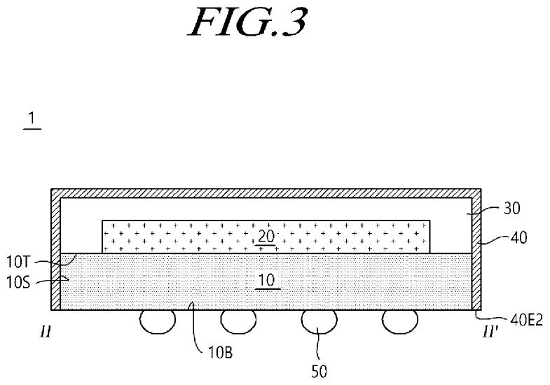

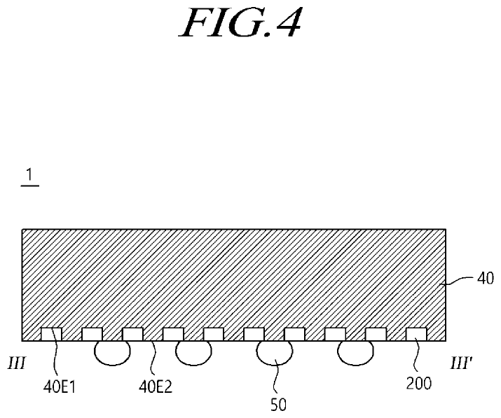

FIG. 1 is a bottom view illustrating a semiconductor package based on an embodiment of the disclosed technology, FIG. 2 is a cross-sectional view taken along the line I-I′ of FIG. 1, FIG. 3 is a cross-sectional view taken along the line II-II′ of FIG. 1, and FIG. 4 is a cross-sectional view taken along the line III-III′ of FIG. 1. FIG. 1 is a bottom view taken by viewing a semiconductor package 1 from the bottom and illustrates a package substrate 10, a shield layer 40, and external connection terminals 50.

Referring to FIGS. 1 to 4, the semiconductor package 1 includes the package substrate 10, a semiconductor chip 20, an encapsulation part 30 and the shield layer 40.

The semiconductor chip 20 may be mounted on a top surface 10T of the package substrate 10. FIGS. 2 and 3 illustrate a structure in which one semiconductor chip 20 is mounted on the package substrate 10, but the disclosed technology is not limited thereto. Although not illustrated, a plurality of semiconductor chips may be horizontally mounted on the package substrate 10, or a plurality of semiconductor chips may be vertically stacked on the package substrate 10. The semiconductor chip 20 may include an integrated circuit (IC).

The encapsulation part 30 may be provided to seal the semiconductor chip 20, thereby protecting the semiconductor chip 20 from the exterior. The encapsulation part 30 may extend to cover and protect the top surface 10T of the package substrate 10. The encapsulation part 30 may be formed of an insulating resin material, such as an epoxy molding compound (EMC). The encapsulation part 30 may be formed by molding an insulating resin material. FIGS. 2 and 3 illustrate that the encapsulation part 30 is formed to completely cover the semiconductor chip 20, but the disclosed technology is not limited thereto. The encapsulation part 30 may also be formed to expose a portion of the semiconductor chip 20.

The shield layer 40 may be formed to cover the surface of the encapsulation part 30 and side surfaces 10S of the package substrate 10. The shield layer 40 might not extend to a bottom surface 10B of the package substrate 10. The bottom surface 10B of the package substrate 10 may be a surface that is on the opposite side of the top surface 10T. The bottom surface 10B of the package substrate 10 may be a surface that is positioned farther from the semiconductor chip 20 than the top surface 10T. The side surfaces 10S of the package substrate 10 may be surfaces that connect the top surface 10T to the bottom surface 10B.

The shield layer 40 may be formed to include a metal material. The metal material may include copper (Cu), nickel (Ni), or stainless steel. The shield layer 40 may include one or at least two of a copper (Cu) layer, a nickel (Ni) layer, and a stainless steel layer. The shield layer 40 may be formed by sputtering deposition of a metal material.

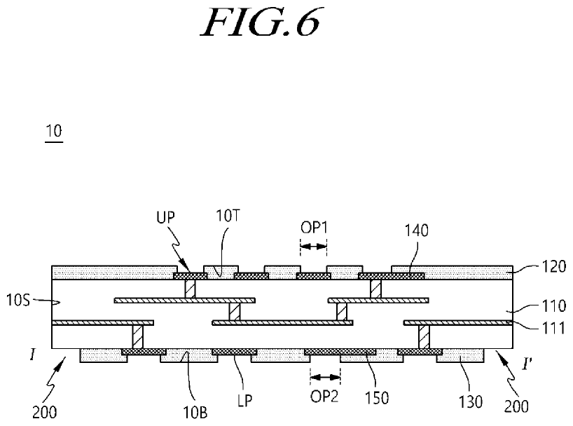

While covering the side surfaces 10S of the package substrate 10, the shield layer 40 may be electrically connected to a ground electrode (111 of FIG. 6) that is disposed on at least one of the side surfaces 10S of the package substrate 10. The shield layer 40 may shield unnecessary electromagnetic waves coming from the exterior. In addition, the shield layer 40 may block electromagnetic waves generated in the semiconductor chip 20 from radiating to the exterior.

The semiconductor package 1 may further include the external connection terminals 50 that are disposed on the bottom surface 10B of the package substrate 10. The external connection terminals 50 may be provided to electrically connect the semiconductor package 1 to an external device, such as another semiconductor package or a module substrate. The external connection terminals 50 may include solder balls.

The package substrate 10 may include a circuit and/or an interconnection structure (not illustrated) for electrically connecting the semiconductor chip 20 to the external connection terminals 50. For example, the package substrate 10 may include a printed circuit board (PCB), an interposer, or a redistribution layer.

The package substrate 10 may include trenches 200 that are positioned at the peripheries of the bottom surface 10B. The trenches 200 may be repeatedly disposed while being spaced apart from each other along the edges of the bottom surface 10B connected to the side surfaces 10S of the package substrate 10.

The trenches 200 may extend in a direction away from the shield layer 40. At least one of the trenches 200 may include a plurality of regions that are disposed in the direction away from the shield layer 40.

Although not illustrated, the package substrate 10 may include a plurality of interconnection patterns and a plurality of conductive vias that electrically connect the interconnection patterns disposed at different levels. The trenches 200 may be disposed outside of the interconnection patterns and the conductive vias. That is to say, the extension length of the trenches 200 may be limited by the interconnection patterns and the conductive vias.

At least one of the trenches 200 of the package substrate 10 may include a first region R1 and a second region R2 that are continuously disposed in the direction away from the shield layer 40 and may have different widths. The trench 200 may have a step portion at the boundary between the first region R1 and the second region R2. The boundary between the first region R1 and the second region R2 may be distinguished by the step portion.

The first region R1 and the second region R2 may have different widths in a direction that is parallel to the direction in which the portion of the shield layer 40 that contacts the corresponding trench 200 extends. The first region R1 may have a first width W1, and the second region R2 may have a second width W2 that is different from the first width W1. Due to a difference in size between the first width W1 and the second width W2, the width of the trench 200 may change abruptly at the boundary between the first region R1 and the second region R2, thereby creating the step portion.

The second region R2 may be disposed between the shield layer 40 and the first region R1, and the trench 200 may be configured such that the second region R2 has a larger width than the first region R1. In other words, the second width W2 may be larger than the first width W1.

The second regions R2 of the trenches 200 may be spaced apart from each other by a distance that is less than the distance between the external connection terminals 50. As illustrated in FIG. 1, the external connection terminals 50 may be spaced apart from each other by a first distance d1, and the second regions R2 of the trenches 200 may be spaced apart from each other by a second distance d2 that is less than the first distance d1.

The shield layer 40 may have a concave-convex structure that exposes the trenches 200 at the lower end of a part covering the side surfaces 10S of the package substrate 10. As illustrated in FIG. 2, first ends 40E1 of the shield layer 40 may be spaced apart from the bottom surface 10B of the package substrate 10 so that the shield layer 40 exposes the trenches 200. As illustrated in FIG. 3, second ends 40E2 of the shield layer 40 may be connected to the bottom surface 10B of the package substrate 10. The first ends 40E1 of the shield layer 40 may be positioned farther from the bottom surface 10B of the package substrate 10 than the second ends 40B2 of the shield layer 40. As the first ends 40E1 and the second ends 40E2 of the shield layer 40 are alternately disposed according to the disposition of the trenches 200, the shield layer 40 may have the concave-convex structure. At the lower ends of the side surfaces 10S of the package substrate 10, the second ends 40E2 of the shield layer 40 and the trenches 200 may be alternately disposed.

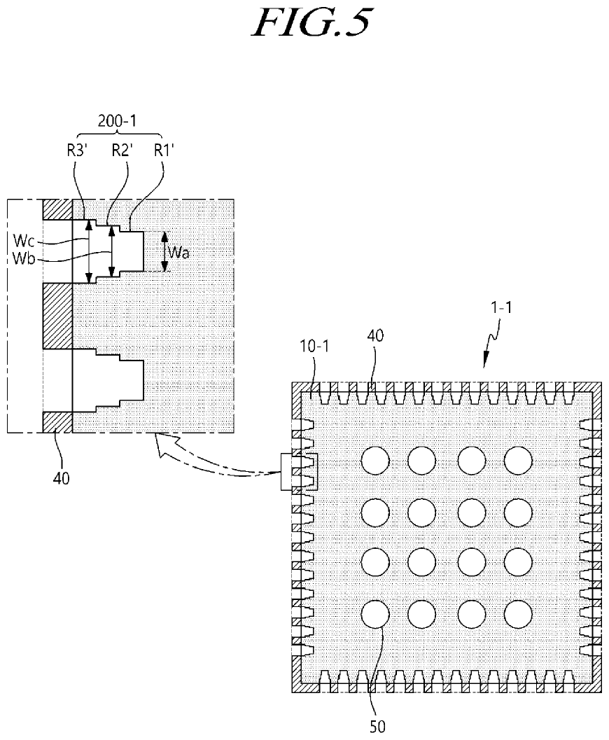

FIG. 1 illustrates a case in which each trench 200 of the package substrate 10 includes two regions, but the disclosed technology is not limited thereto. As illustrated in FIG. 5, a trench 200-1 may include three regions.

FIG. 5 is a bottom view illustrating a semiconductor package based on an embodiment of the disclosed technology.

FIG. 5 is a bottom view taken by viewing a semiconductor package 1-1 from the bottom, and illustrates a package substrate 10-1, a shield layer 40 and external connection terminals 50.

Referring to FIG. 5, at least one of trenches 200-1 of the package substrate 10-1 may include first, second, and third regions R1′, R2′, and R3′ that are continuously disposed in a direction away from the shield layer 40 and may have different widths.

The trench 200-1 may have a first step portion at the boundary between the first region R1′ and the second region R2′ and may have a second step portion at the boundary between the second region R2′ and the third region R3′. The boundary between the first region R1′ and the second region R2′ may be distinguished by the first step portion, and the boundary between the second region R2′ and the third region R3′ may be distinguished by the second step portion.

The first region R1′, the second region R2′, and the third region R3′ may have different widths in a direction that is parallel to the direction in which the portion of the shield layer 40 that contacts the corresponding trench 200-1 extends. The first region R1′ may have a width Wa, the second region R2′ may have a width Wb that is different from the width Wa, and the third region R3′ may have a width Wc that is different from the width Wa and the width Wb. Due to a difference in size between the width Wa and the width Wb, the width of the trench 200-1 may change abruptly at the boundary between the first region R1′ and the second region R2′, thereby creating the first step portion, and due to a difference in size between the width Wb and the width Wc, the width of the trench 200-1 may change abruptly at the boundary between the second region R2′ and the third region R3′, thereby creating the second step portion.

The third region R3′ may be disposed between the shield layer 40 and the second region R2′, and the second region R2′ may be disposed between the third region R3′ and the first region R1′. Among the first, second, and third regions R1′, R2′, and R3′, the third region R3′ may be connected to the shield layer 40, the first region R1′ may be disposed at a farthest position from the shield layer 40, and the second region R2′ may be disposed between the first region R1′ and the third region R3′. In the trench 200-1, the third region R3′ may be configured to have the largest width, the first region R1′ may be configured to have the smallest width, and the second region R2′ may be configured to have a width between that of the first region R1′ and the third region R3′. Namely, the width Wc may be the largest, and the width may decrease in the order of the width Wc, the width Wb, and the width Wa.

FIG. 6 is a cross-sectional view of a package substrate based on an embodiment of the disclosed technology and illustrates a cross-section taken along the line I-I′.

Referring to FIG. 6, a package substrate 10 may include a core layer 110, a top protective layer 120, a bottom protective layer 130, top interconnection patterns 140, and bottom interconnection patterns 150.

Although not illustrated, the core layer 110 may include one insulating layer or a plurality of insulating layers. The insulating layers may be formed of an insulating material such as resin and may have a plate shape.

The core layer 110 may include at least one ground electrode 111. The ground electrode 111 may be disposed in the core layer 110 in the form of an interconnection pattern and may extend to a side surface 10S of the package substrate 10. The ground electrode 111 may be electrically connected to a shield layer (40 of FIG. 2) that is disposed on the side surface 10S of the package substrate 10. In the present embodiment, the ground electrode 111 may be disposed in the core layer 110, but the disclosed technology is not limited thereto. Although not illustrated, it is also possible to dispose a ground electrode on the top surface and/or the bottom surface of the core layer 110.

The top interconnection patterns 140 may be disposed on the top surface of the core layer 110, and the bottom interconnection patterns 150 may be disposed on the bottom surface of the core layer 110. The top interconnection patterns 140 may include top surface substrate pads UP that are connected to a semiconductor chip (20 of FIG. 2). The bottom interconnection patterns 150 may include bottom surface substrate pads LP that are connected to external connection terminals (50 of FIG. 2). The top interconnection patterns 140 may be electrically connected to the corresponding bottom interconnection patterns 150 through circuits and/or interconnection patterns in the core layer 110.

The top protective layer 120 may be disposed on the top surface of the core layer 110 and may cover the top surface of the core layer 110 and the top interconnection patterns 140. The top surface of the top protective layer 120 may configure a top surface 10T of the package substrate 10. The top protective layer 120 may have first openings OP1 that expose the top surface substrate pads UP. The top protective layer 120 may include an insulating material, such as a solder resist.

The bottom protective layer 130 may be disposed on the bottom surface of the core layer 110 and may cover the bottom surface of the core layer 110 and the bottom interconnection patterns 150. The bottom surface of the bottom protective layer 130 may configure a bottom surface 10B of the package substrate 10. The bottom protective layer 130 may have second openings OP2 that expose the bottom surface substrate pads LP. The bottom protective layer 130 may include an insulating material, such as a solder resist.

As the bottom protective layer 130 is partially removed from the edges of the package substrate 10, trenches 200 may be configured. In a process of selectively removing the bottom protective layer 130 to form, in the bottom protective layer 130, the second openings OP2 that expose the bottom surface substrate pads LP, the trenches 200 may be formed together with the second openings OP2.

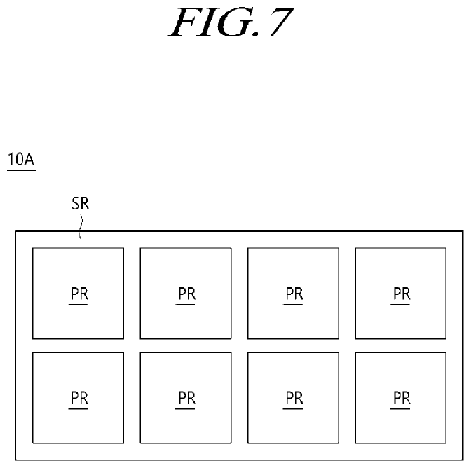

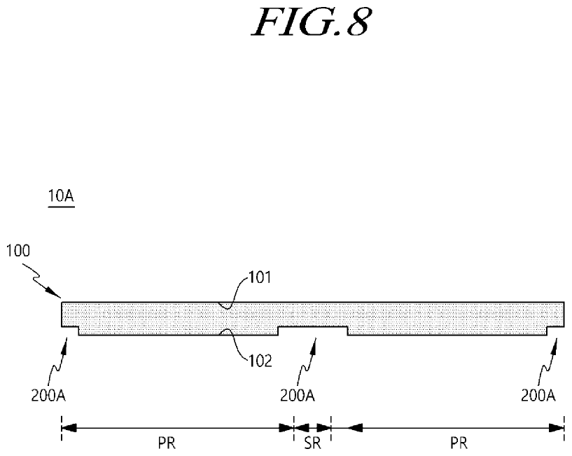

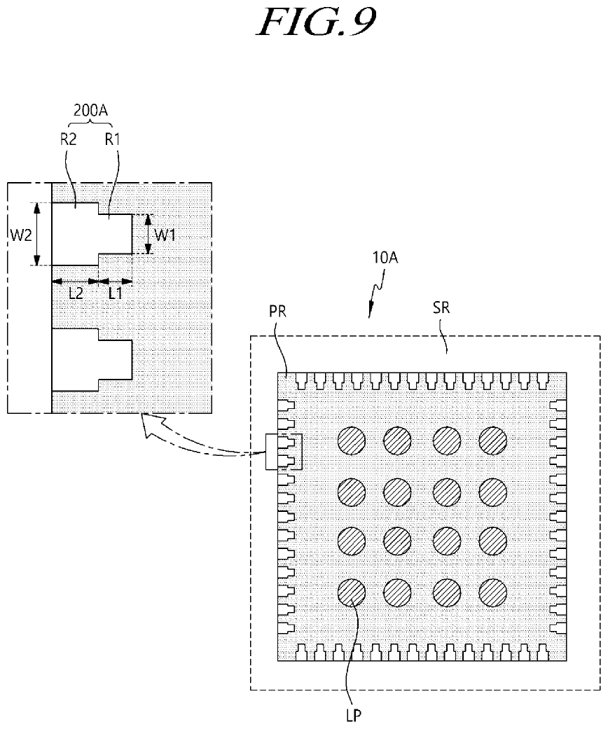

FIG. 7 is a top view schematically illustrating a strip substrate based on an embodiment of the disclosed technology, FIG. 8 is a cross-sectional view schematically illustrating a part of the strip substrate based on the embodiment of the disclosed technology, and FIG. 9 is a bottom view illustrating the strip substrate based on the embodiment of the disclosed technology. FIG. 9 is a bottom view taken by viewing a strip substrate 10A from the bottom and illustrates trenches 200A and bottom surface substrate pads LP of the strip substrate 10A.

Referring to FIG. 7, the strip substrate 10A may include a plurality of package regions PR that are arranged two-dimensionally. A package separation region SR may surround each of the package regions PR. Portions of the package separation region SR may be provided between the package regions PR. By mounting a semiconductor chip in each of the package regions PR, a semiconductor package may be fabricated. By performing a packaging process using the strip substrate 10A, a plurality of semiconductor packages may be simultaneously fabricated.

The package separation region SR may be a region that is cut by a saw blade in a sawing process for separating semiconductor packages fabricated on the strip substrate 10A.

Referring to FIG. 8, the strip substrate 10A may include a substrate body 100 and a plurality of trenches 200A.

A top surface 101 of the substrate body 100 may be a device mounting surface on which semiconductor chips are mounted. Although not illustrated, top surface substrate pads that are connected to the semiconductor chips may be disposed on the top surface 101 of the substrate body 100. A bottom surface 102 of the substrate body 100 may be a surface to which external connection terminals are bonded. Although not illustrated, bottom surface substrate pads that are connected to the external connection terminals may be disposed on the bottom surface 102 of the substrate body 100.

Referring to FIGS. 8 and 9, the trenches 200A may be disposed along the edges of the package region PR on the bottom surface 102 of the substrate body 100. The trenches 200A may extend from the package separation region SR to the package region PR by a predetermined length. In an embodiment, the trenches 200A may traverse the package separation region SR and may extend into two package regions PR that are positioned on both sides of the package separation region SR.

Each of the trenches 200A may include a first region R1 and a second region R2 that are disposed in a line in a direction that is perpendicular to the direction in which the portion of the package separation region SR that contacts the corresponding trench 200A extends, and the first region R1 and the second region R2 may have different widths.

The trench 200A may have a step portion at the boundary between the first region R1 and the second region R2. The boundary between the first region R1 and the second region R2 may be distinguished by the step portion.

The first region R1 and the second region R2 may have different widths in a direction that is parallel to the direction in which the portion of the package separation region SR that contacts the corresponding trench 200A extends. The first region R1 may have a first width W1, and the second region R2 may have a second width W2 that is different from the first width W1. Due to a difference in size between the first width W1 and the second width W2, the width of the trench 200A may change abruptly at the boundary between the first region R1 and the second region R2, thereby creating the step portion.

The second region R2 may be disposed between the package separation region SR and the first region R1, and the trench 200A may be configured such that the second region R2 has a larger width than the first region R1. That is to say, the second width W2 may be larger than the first width W1.

In the direction that is perpendicular to the direction in which the portion of the package separation region SR that contacts the corresponding trench 200A extends, the first region R1 may have a length of L1, and the second region R2 may have a length of L2. The length L2 may have a value that is determined based on the cutting width of the package region PR that may occur during a normal sawing process. For example, the length L2 may have a size of 15 to 50 μm. The length L1 may have a size obtained by subtracting the length L2 from the length (e.g., 100 μm) of the trench 200A in the package region PR.

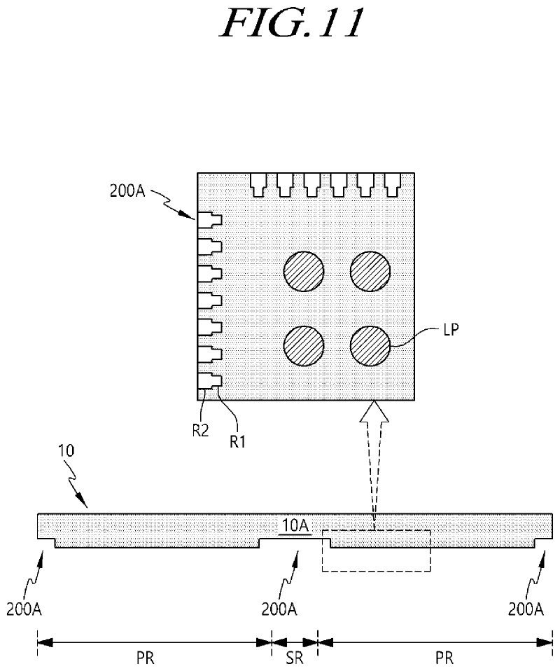

As will be described later with reference to FIGS. 11 to 18B, after mounting a semiconductor chip on a strip substrate and molding the semiconductor chip with an encapsulation part, an individualized semiconductor package may be formed by cutting the encapsulation part and the strip substrate along the package separation region SR through a sawing process. In a state in which the semiconductor package is disposed on a base substrate, a metal layer may be formed on the surface of the encapsulation part, the side surfaces of a package substrate and the surface of the base substrate, and then, by separating the package substrate from the base substrate, a shield layer that covers the surface of the encapsulation part and the side surfaces of the package substrate may be formed.

In the course of forming the metal layer, a metal material may be continuously formed along the side surfaces of the package substrate and the surface of the base substrate that is connected to the side surfaces of the package substrate. In a process of separating the package substrate from the base substrate, as the metal layer formed on the side surfaces of the package substrate and the surface of the base substrate is torn, a conductive burr may be created. The conductive burr may stick to the surface of the semiconductor package in the course of performing a subsequent process that causes an unwanted contact between electrical connections. In other words, the conductive burr may serve as a cause of a defect, such as a short.

The metal layer might not be formed in portions where the trenches 200A are positioned. The trenches 200A may be provided to cause the metal layer to be discontinuously formed at portions where the surface of the base substrate and the side surfaces of the package substrate are connected. Due to the presence of the trenches 200A, the metal layer may be divided into a plurality of portions where the surface of the base substrate and the side surfaces of the package substrate are connected. Accordingly, in a subsequent process of separating the package substrate from the base substrate, the divided portions of the metal layer, not the entire metal layer, may be separated. Because the divided portions of the metal layer are separated, the creation of a conductive burr may be suppressed, or a shorter conductive burr may be created.

Due to factors, such as in process and equipment, cutting may be performed during a sawing process that decreases the size of a semiconductor package decreases to be smaller than a target dimension, thus decreasing the length of the trenches 200A. Although not illustrated, such a sawing process may result in some trenches 200A having only the first regions R1 since the second regions R2 are cut. When cutting is excessively performed compared to the target dimension, the trenches 200A may be completely removed.

It is necessary to manage the sawing process so that the trenches 200A are not completely removed, and to this end, it is necessary to determine a level at which the trenches 200A are cut during the sawing process. In the embodiment of the disclosed technology, by checking whether the first and second regions R1 and R2 of the trenches 200A are present after the sawing process, the cutting level of the trenches 200A may be determined.

FIG. 9 illustrates a case in which the trench 200A includes two regions, but the disclosed technology is not limited thereto. The trench 200A may include at least three regions.

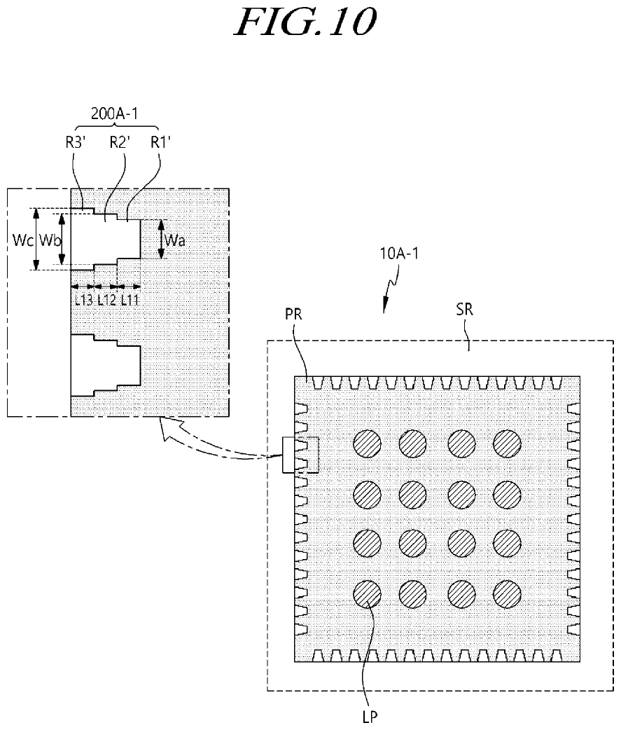

FIG. 10 is a bottom view illustrating a strip substrate based on an embodiment of the disclosed technology and illustrates trenches 200A-1 and bottom surface substrate pads LP of a strip substrate 10A-1.

Referring to FIG. 10, each of the trenches 200A-1 of the strip substrate 10A-1 may include first, second and third regions R1′, R2′ and R3′ which are continuously disposed in a direction away from a package separation region SR and have different widths.

The trench 200A-1 may have a first step portion at the boundary between the first region R1′ and the second region R2′ and may have a second step portion at the boundary between the second region R2′ and the third region R3′. The boundary between the first region R1′ and the second region R2′ may be distinguished by the first step portion, and the boundary between the second region R2′ and the third region R3′ may be distinguished by the second step portion.

The first region R1′, the second region R2′ and the third region R3′ may have different widths in a direction that is parallel to the direction in which the portion of the package separation region SR that contacts the corresponding trench 200A-1 extends. The first region R1′ may have a width Wa, the second region R2′ may have a width Wb that is different from the width Wa, and the third region R3′ may have a width Wc that is different from the width Wa and the width Wb. Due to a difference in size between the width Wa and the width Wb, the width of the trench 200A-1 may change abruptly at the boundary between the first region R1′ and the second region R2′, thereby creating the first step portion, and due to a difference in size between the width Wb and the width Wc, the width of the trench 200A-1 may change abruptly at the boundary between the second region R2′ and the third region R3′, thereby creating the second step portion.

The third region R3′ may be disposed between the package separation region SR and the second region R2′, and the second region R2′ may be disposed between the third region R3′ and the first region R1′. Among the first, second, and third regions R1′, R2′, and R3′, the third region R3′ may be disposed closest to the package separation region SR, the first region R1′ may be disposed farthest from the package separation region SR, and the second region R2′ may be disposed between the first region R1′ and the third region R3′. In the trench 200A-1, the third region R3′ may be configured to have the largest width, the first region R1′ may be configured to have the smallest width, and the second region R2′ may be configured to have a width between that of the first region R1′ and the third region R3′. Namely, the width Wc may be the largest, and the width may decrease in the order of the width Wc, the width Wb, and the width Wa.

The first region R1′ may have a length of L11, the second region R2′ may have a length of L12, and the third region R3′ may have a length of L13. The length L13 may have a value that is determined based on the cutting width of a package region PR that may occur during a normal sawing process. For example, the length L13 may have a size of 15 to 50 μm.

According to the embodiment of the disclosed technology, by configuring the trenches 200A-1 to have at least three regions, the cutting level of the trenches 200A-1 may be determined based on at least three levels, and a sawing process may be managed based on a determined level.

FIGS. 11 to 18B are views for explaining a method for manufacturing a semiconductor package based on an embodiment of the disclosed technology.

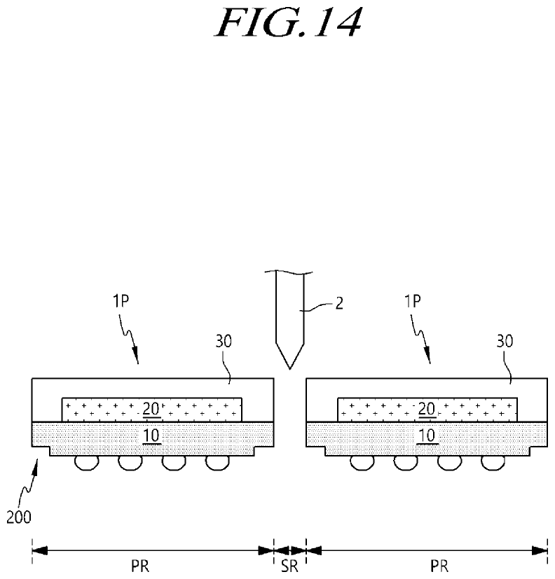

Referring to FIG. 11, a strip substrate 10A that includes a plurality of trenches 200A may be prepared. The trenches 200A may be a pre-structure for implementing the trenches 200 of FIG. 14.

Each of the plurality of trenches 200A may include first and second regions R1 and R2 that are disposed in a line in a direction that is perpendicular to the direction in which a portion of a package separation region SR that contacts the corresponding trench 200A extends, and the first and second regions R1 and R2 may have different widths. Since the first and second regions R1 and R2 of the strip substrate 10A are described above with reference to FIGS. 7 to 9, repeated description of the same content will be omitted.

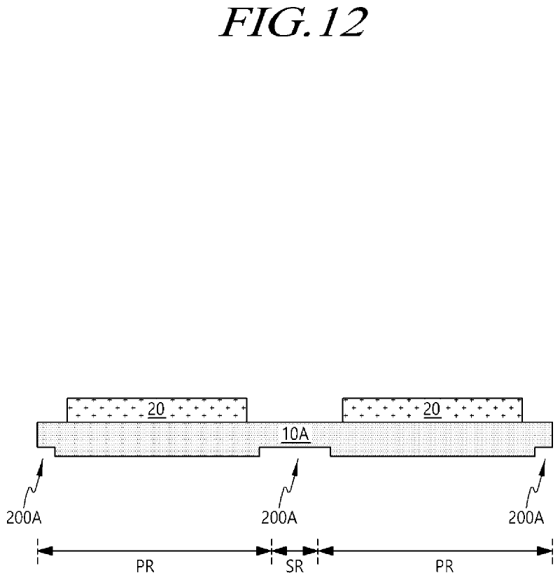

Referring to FIG. 12, a step of mounting a semiconductor chip 20 on the top surface of each of package regions PR of the strip substrate 10A may be performed.

For example, although not illustrated, the semiconductor chip 20 may include, on an active surface, a plurality of chip pads and a plurality of bumps that are connected to the plurality of chip pads. The semiconductor chip 20 may be flip-chip bonded onto the strip substrate 10A such that the plurality of bumps are bonded to top surface substrate pads of the strip substrate 10A.

For another example, although not illustrated, an inactive surface of the semiconductor chip 20, which is opposite to the active surface of the semiconductor chip 20 on which the chip pads are positioned, may be attached to the top surface of the strip substrate 10A using an adhesive, and the chip pads of the semiconductor chip 20 and the top surface substrate pads of the strip substrate 10A may be connected by using wires.

The disclosed technology illustrates a structure in which one semiconductor chip 20 is mounted in each package region PR, but the disclosure is not limited thereto. Although not illustrated, a plurality of semiconductor chips may be horizontally mounted in each package region PR, or a plurality of semiconductor chips may be vertically stacked in each package region PR.

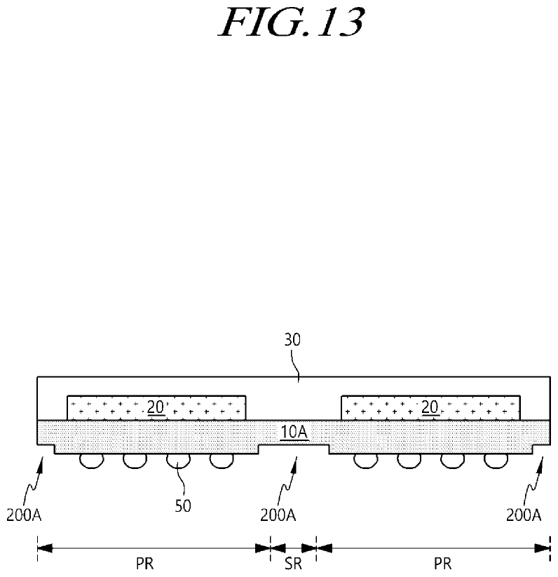

Referring to FIG. 13, a step of forming, on the top surface of the strip substrate 10A, an encapsulation part 30 that seals the semiconductor chip 20 and attaching external connection terminals 50 to the bottom surface of the strip substrate 10A may be performed.

As illustrated in the drawing, the encapsulation part 30 may be formed in an integral type that covers all of the plurality of package regions PR of the strip substrate 10A. However, if necessary, the encapsulation part 30 may be separately formed for each package region PR. The encapsulation part 30 may be formed by injection-molding an insulating material, such as an epoxy molding compound (EMC), on the strip substrate 10A.

Referring to FIG. 14, a step of cutting the encapsulation part 30 and the strip substrate 10A (see FIG. 13) through a sawing process and thereby forming individualized semiconductor packages 1P may be performed.

The encapsulation part 30 and the strip substrate 10A (see FIG. 13) may be cut along the package separation region SR by using a saw blade 2. The semiconductor package 1P may be a pre-structure for implementing the semiconductor package 1 of FIG. 2.

The sawing process may be performed as a full cut process. The full cut process means a process of cutting the top and bottom surfaces of a structure at once using a saw blade. When compared to a process in which a part of a structure (e.g., a substrate formed with an encapsulation part) is primarily cut and then the remaining uncut part is secondarily cut to separate semiconductor packages, the full cut process may form a smooth cut surface and may form the semiconductor packages 1P to have a uniform size.

During the sawing process, not only is the package separation region SR cut, the package region PR may also be cut. Due to factors, such as in process and equipment, the package region PR may be excessively cut compared to a target dimension during the sawing process, and thus, trenches 200 may be completely removed. Causes of excessive cutting may include a width deviation between the saw blade 2 and the package separation region SR, poor flatness of the saw blade 2, vibration of equipment, a variation in the cutting width of the saw blade 2 due to rotation, and a cutting line shift by the locking tolerance between a tool and equipment when changing a tool for each product. In particular, due to a case in which a saw blade is barely worn at an initial stage after mounting a new saw blade or a locking tolerance immediately after newly mounting a tool in equipment due to change of a product to be manufactured, there is a high possibility of excessive cutting occurring.

After the sawing process, a step of inspecting the appearance of the trenches 200 and evaluating the sawing process capability may be performed.

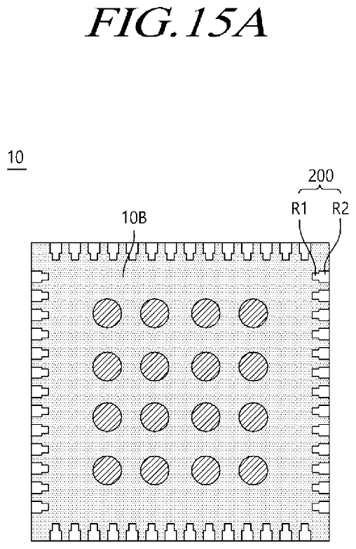

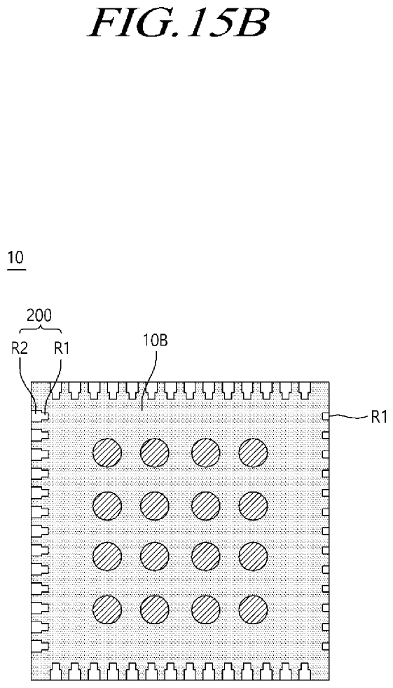

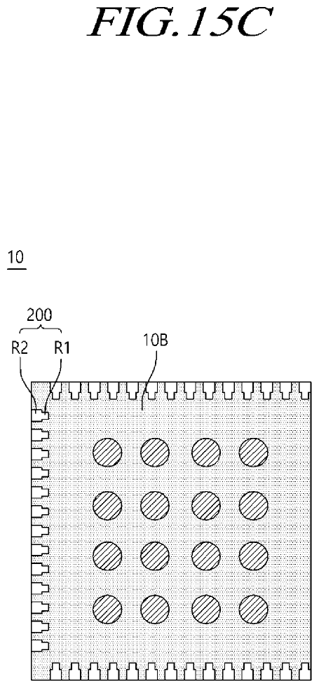

As illustrated in FIG. 15A, the first and second regions R1 and R2 of the trenches 200 may be observed on all sides of a bottom surface 10B of a package substrate 10. This corresponds to a case in which only portions of the second regions R2 are cut on all sides of the package substrate 10. In this case, it may be evaluated that sawing process capability is normal.

As illustrated in FIG. 15B, only the first regions R1 of the trenches 200 may be observed, and the second regions R2 might not be observed on at least one of the sides of the bottom surface 10B of the package substrate 10. This corresponds to a situation in which cutting occurs on at least one of the side surfaces of the package substrate 10 to a level exceeding the length of the second regions R2, and thus, the second regions R2 are removed and only the first regions R1 partially remain. In this situation, it may be evaluated that the sawing process capability is beyond what is to be expected and needs management. In this case, by conducting inspection of equipment, raw materials, and tools, measures may be taken to restore the sawing process capability to what is to be expected.

As illustrated in FIG. 15C, both the first and second regions R1 and R2 of the trenches 200 may be cut on at least one of the sides of the bottom surface 10B of the package substrate 10, and thus, might not be seen. This corresponds to a situation in which both portions of the trenches 200 are removed due to excessive cutting on at least one of the side surfaces of the package substrate 10, and it may be evaluated that sawing process capability is out of specification. In this case, measures may be taken by stopping the sawing equipment, re-setting the sawing equipment, and then restarting the sawing equipment.

Inspection of the appearance of the trenches 200 may be separately performed but may also be performed in parallel with replacing an existing equipment tool, replacing a saw blade, or a package appearance inspection performed on a regular basis.

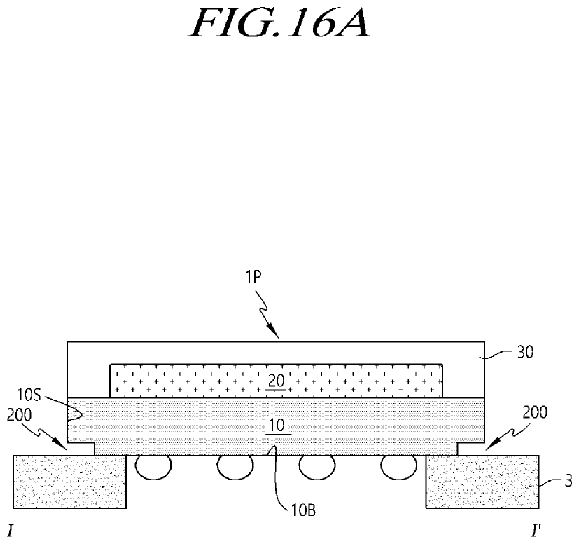

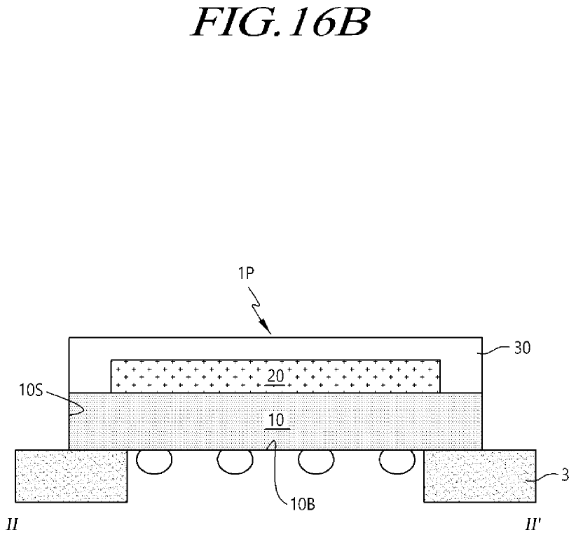

Referring to FIGS. 16A and 16B, a step of disposing the semiconductor package 1P on a base substrate 3 is performed. FIG. 16A is a cross-sectional view taken along the line I-I′, illustrating a portion in which the trenches 200 are positioned. FIG. 16B is a cross-sectional view taken along the line II-II′, illustrating a portion in which the trenches 200 are not positioned.

As illustrated in FIG. 16A, due to the presence of the trenches 200, some portions of the edges of the package substrate 10 might not contact the surface of the base substrate 3 and may be spaced apart from the surface of the base substrate 3. Due to the presence of the trenches 200, some portions of side surfaces 10S of the package substrate 10 may be spaced apart from the base substrate 3. Accordingly, open regions may be provided between the package substrate 10 and the base substrate 3.

Meanwhile, as illustrated in FIG. 16B, in regions where there are no trenches 200, the side surfaces 10S of the package substrate 10 may contact the surface of the base substrate 3.

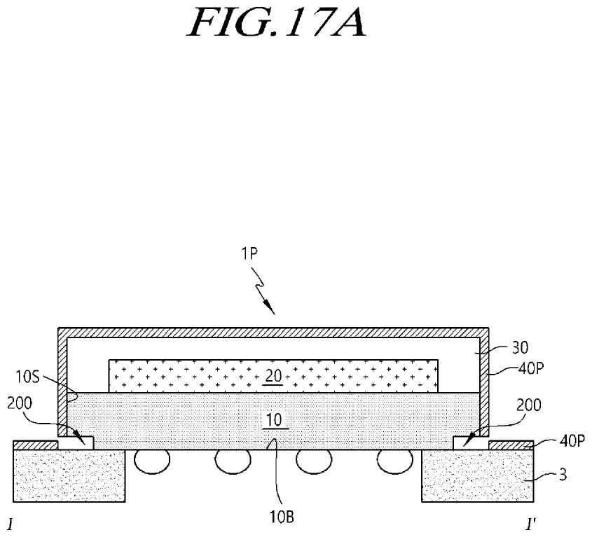

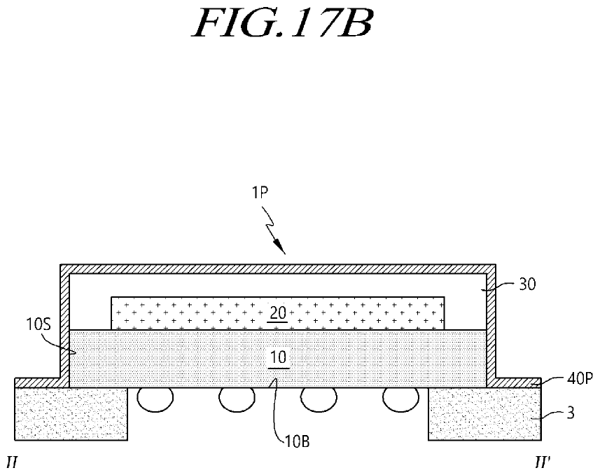

Referring to FIGS. 17A and 17B, a step of forming a metal layer 40P on the semiconductor package 1P and the base substrate 3 may be performed. FIG. 17A is a cross-sectional view taken along the line I-I′, illustrating a portion in which the trenches 200 are positioned. FIG. 17B is a cross-sectional view taken along the line II-II′, illustrating a portion in which the trenches 200 are not positioned.

The metal layer 40P may be formed by sputtering deposition. The metal layer 40P may cover the surface of the encapsulation part 30 and the side surfaces 10S of the package substrate 10 and may extend to cover a portion of the surface of the base substrate 3. Since the metal layer 40P is formed by sputtering a metal material simultaneously on the semiconductor package 1P and the base substrate 3, the metal layer 40P may also be formed on the surface of the base substrate 3.

Since openings are provided between the package substrate 10 and the base substrate 3 in portions in which the trenches 200 of the package substrate 10 are positioned, as illustrated in FIG. 17A, the metal layer 40P might not be formed at positions that overlap with the trenches 200. Since the metal material is not substantially sputtered into the trenches 200, the metal layer 40P may be formed to expose the trenches 200.

As illustrated in FIG. 17B, the metal layer 40P may be continuously formed along the side surfaces 10S of the package substrate 10 and the surface of the base substrate 3 in regions in which there are no trenches 200.

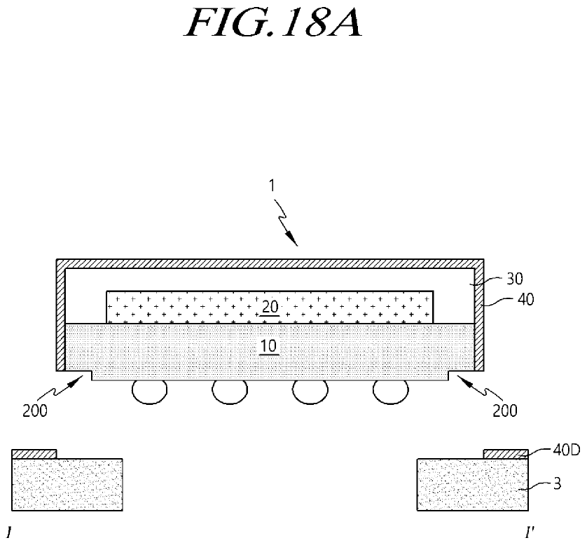

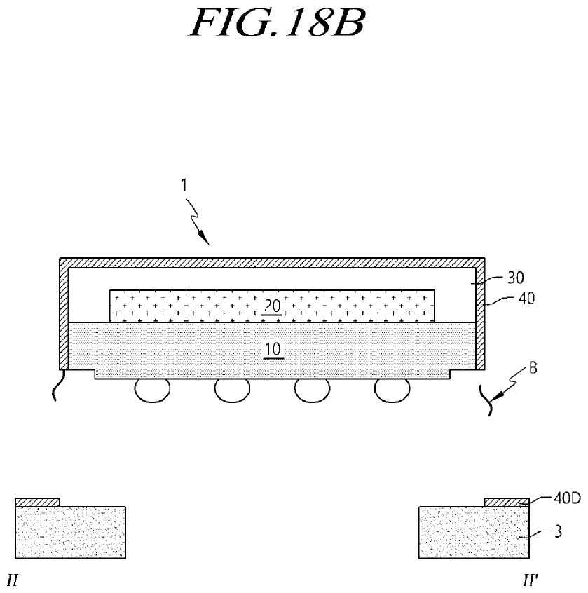

Referring to FIGS. 18A and 18B, a step of separating the package substrate 10 from the base substrate 3 and thereby dividing the metal layer 40P into a shield layer 40 and a remaining metal layer 40D may be performed. FIG. 18A is a cross-sectional view taken along the line I-I′, illustrating a portion in which the trenches 200 are positioned. FIG. 18B is a cross-sectional view taken along the line II-II′, illustrating a portion in which the trenches 200 are not positioned.

As illustrated in FIG. 18B, as the metal layer 40P (see FIG. 17B) is torn in regions in which the surface of the base substrate 3 and the side surfaces 10S of the package substrate 10 contact each other, the metal layer 40P (see FIG. 17B) may be divided into the shield layer 40 that covers the surface of the encapsulation part 30, the side surfaces 10S of the package substrate 10 (see FIG. 17B), and the remaining metal layer 40D that remains on the base substrate 3.

As the metal layer 40P (see FIG. 17B) is torn, a conductive burr B may be created. However, since the regions in which the surface of the base substrate 3 and the side surfaces 10S of the package substrate 10 contact each other are divided due to the presence of the trenches 200, the conductive burr B may have a length that is shorter than the distance between the trenches 200. Accordingly, it is possible to suppress or prevent the occurrence of a defect, such as a short between metal electrodes exposed in the semiconductor package 1 based on the conductive burr B.

As illustrated in FIG. 18A, since the metal layer 40P (see FIG. 17A) is divided, already in the forming step, in regions in which the trenches 200 are positioned, no additional conductive burr B may be created.

Although exemplary embodiments of the present disclosure have been described for illustrative purposes, those skilled in the art will appreciate that various modifications, additions and substitutions are possible, without departing from the scope and spirit of the present disclosure. Therefore, the embodiments disclosed above and in the accompanying drawings should be considered in a descriptive sense only and not for limiting the technological scope. The technological scope of the present disclosure is not limited by the embodiments and the accompanying drawings.

What is claimed is:

1. A method for manufacturing a semiconductor package, comprising:
forming a strip substrate that has a package region and a package separation region surrounding the package region and that includes a plurality of trenches disposed at an edge of the package region of a bottom surface;
mounting a semiconductor chip on the package region of a top surface of the strip substrate;
sealing the semiconductor chip with an encapsulation part;
forming an individualized semiconductor package by cutting the encapsulation part and the strip substrate along the package separation region through a sawing process;
inspecting an appearance of trenches of the semiconductor package;
evaluating a capability of the sawing process based on a result of the inspecting of the appearance of the trenches; and
forming a shield layer on a side surface of a package substrate of the semiconductor package and a surface of the encapsulation part,
wherein each of the plurality of trenches of the strip substrate includes first and second regions that are continuously disposed in a direction that is perpendicular to a direction in which a portion of the package separation region that contacts the corresponding trench extends,
wherein the first and second regions have different widths, and
wherein the inspecting of the appearance of the trenches includes checking a presence of the first and second regions of the trenches of the semiconductor package.

2. The method according to claim 1, wherein each of the plurality of trenches of the strip substrate is provided such that the first region and the second region have different widths in a direction that is parallel to a direction in which a portion of the package separation region that contacts the corresponding trench extends.

3. The method according to claim 1, wherein each of the plurality of trenches of the strip substrate is provided such that the second region is disposed between the package separation region, and
wherein the first region and the first region has a width that is less than the second region.

4. The method according to claim 1, wherein each of the plurality of trenches of the strip substrate is provided to have a step portion at a boundary between the first region and the second region.

5. The method according to claim 1, wherein each of the plurality of trenches of the strip substrate is provided such that the second region is disposed between the package separation region and the first region, and
wherein the second region has a length of 15 to 50 μm in the direction that is perpendicular to the direction in which the portion of the package separation region that contacts the corresponding trench extends.

6. A semiconductor package comprising:
a package substrate including a plurality of trenches that are disposed at a periphery of a bottom surface of the package substrate;
a semiconductor chip disposed on a top surface of the package substrate;
an encapsulation part disposed on the top surface of the package substrate that seals the semiconductor chip; and
a shield layer disposed on a surface of the encapsulation part and a side surface of the package substrate,
wherein at least one of the plurality of trenches includes first and second regions that are continuously disposed in a direction that is perpendicular to a direction in which a portion of the shield layer that contacts the corresponding trench extends, and
wherein the first and second regions have different widths.

7. The semiconductor package according to claim 6, wherein the first region and the second region have different widths in a direction that is parallel to a direction in which a portion of the shield layer that contacts the corresponding trench extends.

8. The semiconductor package according to claim 6,
wherein the second region is disposed between the shield layer and the first region, and
wherein a width of the first region is less than a width of the second region.

9. The semiconductor package according to claim 6, wherein the at least one trench has a step portion at a boundary between the first region and the second region.

10. The semiconductor package according to claim 6, wherein the plurality of trenches are spaced apart from each other and are repeatedly disposed along edges at which the bottom surface of the package substrate and the side surface of the package substrate meet.

11. The semiconductor package according to claim 6, wherein the shield layer has a concave-convex structure that exposes the plurality of trenches at a part covering the side surface of the package substrate.

12. The semiconductor package according to claim 6, further comprising:
a plurality of external connection terminals attached to the bottom surface of the package substrate.

13. The semiconductor package according to claim 12, wherein the second regions of the plurality of trenches are spaced apart from each other by a distance that is narrower than a distance between the plurality of external connection terminals.

14. The semiconductor package according to claim 12, wherein the package substrate comprises:
a core layer;
a plurality of bottom surface substrate pads disposed under the core layer, the plurality of external connection terminals being attached to the plurality of bottom surface substrate pads; and
a bottom protective layer, disposed under the core layer, having a plurality of openings that expose the plurality of bottom surface substrate pads and providing the bottom surface of the package substrate,
wherein the plurality of trenches are configured in the bottom protective layer.

15. The semiconductor package according to claim 14,
wherein the bottom protective layer comprises a solder resist layer, and
wherein the plurality of external connection terminals comprise solder balls.

16. A strip substrate comprising:
a substrate body having a package region and a package separation region that surrounds the package region; and
a plurality of trenches disposed along an edge of a bottom surface of the package region,
wherein each of the plurality of trenches includes first and second regions that are continuously disposed in a direction that is perpendicular to a direction in which a portion of the package separation region that contacts the corresponding trench extends, and
wherein the first and second regions have different widths.

17. The strip substrate according to claim 16, wherein each of the plurality of trenches is configured such that the first region and the second region have different widths in a direction that is parallel to a direction in which a portion of the package separation region that contacts the corresponding trench extends.

18. The strip substrate according to claim 16, wherein each of the plurality of trenches is configured such that the second region is disposed between the package separation region and the first region, and
wherein the first region has a width that is less than the second region.

19. The strip substrate according to claim 16, wherein each of the plurality of trenches is configured to have a step portion at a boundary between the first region and the second region.

20. The strip substrate according to claim 16, wherein each of the plurality of trenches is configured such that the second region is disposed between the package separation region and the first region, and
wherein the second region has a length of 15 to 50 μm in the direction that is perpendicular to the direction in which the portion of the package separation region that contacts the corresponding trench extends.
